(19) United States
(12) Patent Application Publication
(10) Pub. No.: US 2021/0408250 A1
(43) Pub. Date: Dec. 30, 2021

(54) METHOD OF DISTRIBUTING METAL LAYERS IN A POWER DEVICE

(71) Applicant: Monolithic Power Systems, Inc., San Jose, CA (US)

(72) Inventor: Joel McGregor, Kirkland, WA (US)

(21) Appl. No.: 16/910,964

(22) Filed: Jun. 24, 2020

(51) Int. Cl. H01L 29/423; H01L 29/417; H01L 29/40

(52) U.S. Cl. CPC H01L 29/4232; H01L 29/402; H01L 29/41725

(57) ABSTRACT

A metal distributing method of a FET (Field Effect Transistor) device, having: depositing a first dielectric layer on a planar silicon surface; etching a first level metal layer pattern in the first dielectric layer; filling in a first level metal layer in openings determined by the first level metal layer pattern; depositing a second dielectric layer on the first dielectric layer and the first level metal layer; etching a second level metal layer pattern in the second dielectric layer; and filling in a second level metal layer in openings determined by the second level metal layer pattern; the first level metal layer and the second level metal layer are contacted directly, with no via layer in between.

### TECHNICAL FIELD

The present invention generally relates to semiconductor devices, and more particularly but not exclusively relates to methods of fabricating power FET (Field Effect Transistor) devices.

### BACKGROUND

Lateral power FETs have all three terminals (source, gate, and drain) contacted on one side of the wafer. FIG. 1 schematically shows a top view of a prior art power FET 10 with first level metal layer. FIG. 1 shows an efficient layout which is alternating source and drain stripes, with the gate stripes contacted by a first level metal layer only at stripe ends. The first level metal layer also consists of metal stripes alternately covers and connected to source and drain.

Advancing FET technology aims to reduce the FET pitch, which also requires to reduce the first level metal pitch. Reduced metal pitch requires reduced metal thickness in manufacturing, and this reduced metal thickness causes increased metal resistance, and reduced current-carrying capability, limited by electromigration in the metal lines. These problems are typically solved by adding extra metal layers on top of the first level, fine-pitch metal layer, which can run parallel with or perpendicular to the first level metal stripes.

For lateral power FETs integrated with other circuitry in an integrated circuit, extra metal layers are usually required for the other circuitry. So adding one or more metal levels to the power FET metal system does not increase total mask count or cost. However, in a discrete implementation, where the FET device is built on its own die or with only a few simple supporting devices which do not require multilayer metal interconnect, adding more metal layers is a significant cost penalty.

A further, severe restriction on the width of the first level drain metal stripe occurs in lateral power FETs incorporating a field plate contact, as shown in a cross section view of a prior art power FET 20 with two level metal layers M1 and M2 in FIG. 2. In FIG. 2, there is a field plate contact stripe FPC, not covered by metal, between gate G and drain contact DC. The field plate contact FPC does not touch the silicon surface. It is connected to the source contact SC or gate G using first level metal stripe M12 at the stripe ends, like the gate shown in FIG. 1. Since the field plate contact FPC is connected to source contact SC or gate G, the first level metal stripe M11 connected to the drain contact DC need to be spaced away from it. If the first level metal stripe M11 were to overlap the field plate contact FPC, it would short-circuit the drain contact DC to either source contact SC or gate G. This layout constraint restricts the width of the first level metal stripe M11 and makes necessary a second level metal layer M2, and a via layer V1 connecting first and second level metal layer M1 and M2, which adds two masking steps, one for the second level metal layer M2, one for the via layer V1.

There is a need to save masking steps while still have capability to distribute large current by metal layers.

### SUMMARY

It is an object of the present invention to provide a metal distributing process to a power FET allowing the addition of a thick copper metal layer on top of the first-level fine-pitch metal layer with less masking steps.

The embodiments of the present invention are directed to a metal distributing method for a FET (Field Effect Transistor) device, comprising: depositing a first dielectric layer on a planar silicon surface; etching a first level metal layer pattern in the first dielectric layer; filling in a first level metal layer in openings determined by the first level metal layer pattern; depositing a second dielectric layer on the first dielectric layer and the first level metal layer; and etching a second level metal layer pattern in the second dielectric layer; filling in a second level metal layer in openings determined by the second level metal layer pattern; wherein the first level metal layer and the second level metal layer are contacted directly, with no via layer in between.

The embodiments of the present invention are also directed to a FET (Field Effect Transistor) device, comprising: a first level metal layer, patterned to be connected to a source contact and a drain contact, wherein areas of the first level metal layer connected to the source contact are separated from areas of the first level metal layer connected to the drain contact; and a second level metal layer, patterned to be directly contacted to the first level metal layer, with no via layer in between, wherein areas of the second level metal layer electrically connected to the source contact via the first level metal layer are separated from areas of the second level metal layer electrically connected to the drain contact via the first level metal layer.

The embodiments of the present invention are further directed to a FET (Field Effect Transistor) device, comprising: a first dielectric layer on a planar silicon surface; a first level metal layer damascened in the first dielectric layer; a second dielectric layer on the first dielectric layer and the first level metal layer; and a second level metal layer damascened in the second dielectric layer; wherein the first level metal layer and the second level metal layer are contacted directly, with no via layer in between.

### BRIEF DESCRIPTION OF THE DRAWINGS

The present invention can be further understood with reference to the following detailed description and the appended drawings, wherein like elements are provided with like reference numerals. The drawings are only for illustration purpose. They may only show part of the devices and are not necessarily drawn to scale.

FIG. 1 schematically shows a top view of a prior art power FET 10 with first level metal layer.

FIG. 2 schematically shows a cross section view of a prior art power FET 20 with two level metal layers.

FIG. 3 shows a cross section view of a FET device 30 in accordance with an embodiment of the present invention.

FIG. 4 shows a top view of the FET device 30 in FIG. 3 in accordance with an embodiment of the present invention.

FIG. 5A˜H shows a metal distributing process of the FET device 30 in accordance with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

The terms “left,” right,” “in,” “out,” “front,” “back,” “up,” “down, “top,” “atop”, “bottom,” “over,” “under,” “beneath,” “above,” “below” and the like in the description and the claims, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein.

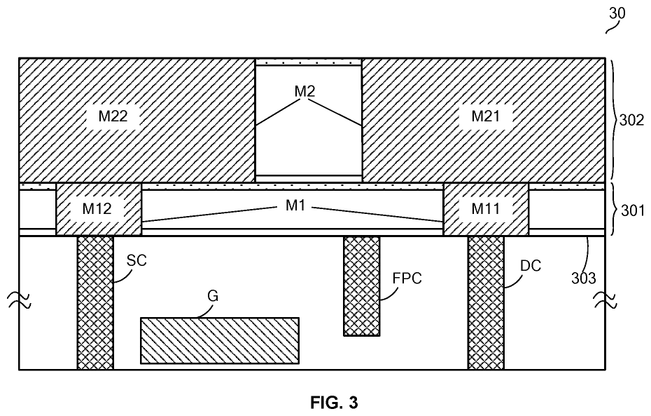

FIG. 3 shows a cross section view of a FET device 30 in accordance with an embodiment of the present invention. As shown in FIG. 3, the FET device comprises: a first dielectric layer 301 on an underlying planar silicon surface 303; a first level metal layer M1 damascened in the first dielectric layer 301; a second dielectric layer 302 on the first dielectric layer 301 and the first level metal layer M1; and a second level metal layer M2 damascened in the second dielectric layer 302.

The cross section view in FIG. 3 shows part of the power FET 30 for illustration, not the whole device. The power FET 30 may have a large extension with drain and source alternating distributed.

In FIG. 3, the first dielectric layer 301 is patterned by a masking step to define the location of the first level metal layer M1. And in the same way, the second dielectric layer 302 is patterned by a masking step to define the location of the second level metal layer M2. As shown in FIG. 3, the first level metal layer M1 comprises stripes (lines) M12 and M11 respectively connected to the source contact SC and the drain contact DC, wherein the stripe M12 and the stripe M11 are spaced away. Similarly, the second level metal layer M2 comprises stripes M22 and M21 respectively connected to the stripes M12 and M11, wherein the stripe M22 and the stripe M21 are spaced away.

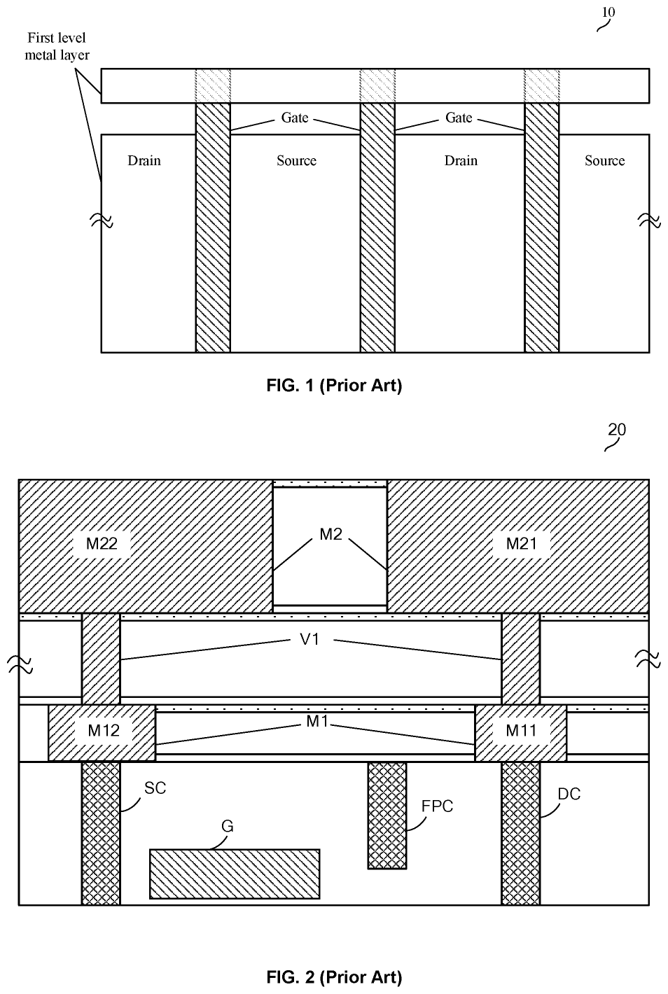

In the prior art power FET 20 shown in FIG. 2, a via layer V1 is deposited on the first dielectric layer. However, in the present invention, as shown in FIG. 3, a main, thick, copper interconnect layer, i.e., the second level metal layer M2 instead of the via layer V1, is distributed on the first dielectric layer 301, and has direct contact to the first level metal layer M1, which means the first level metal layer M1 and the second level metal layer M2 are contacted directly, with no via layer in between. The thickness of the second dielectric layer 302 may be the maximum compatible with the metal pitch, which is set by the underlying power FET pitch.

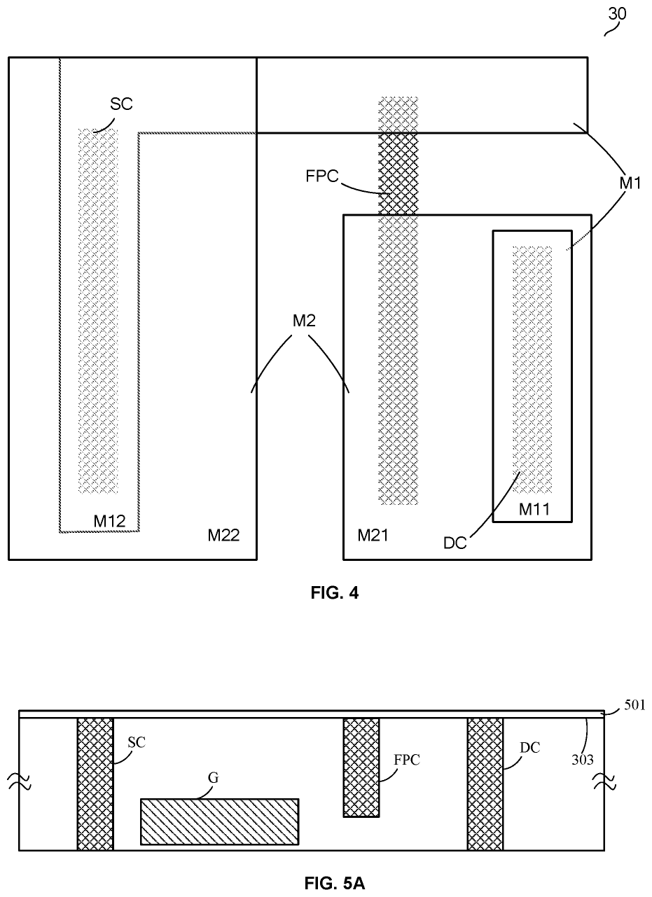

FIG. 4 shows a top view of the FET device 30 in FIG. 3 in accordance with an embodiment of the present invention. As shown in FIG. 4, the stripe M12 of the first level metal layer M1 covers the source contact SC and has an extension at stripe ends to overlap an end of the field plate contact FPC, connecting the field plate contact FPC to a source potential (not shown in FIG. 4). Except the stripe end, there is no first level metal layer over the field plate contact FPC, and the field plate contact FPC is isolated from the overlying second level metal stripe M21 connecting to the drain contact DC. In FIG. 4, area of the second level metal layer M2, i.e., M22, electrically connected to the source contact SC via the first level metal layer M1, i.e., M12, is separated from area of the second level metal layer M2, i.e., M21, electrically connected to the drain contact DC via the first level metal layer M1, i.e., M11, to avoid short of the source and drain of the FET device 30.

In one embodiment, a thickness of the first level metal layer M1 could be in a range of 0.12 μm ˜0.38 μm, and has both a minimum line width and a minimum space between lines of 0.12 μm, making its minimum pitch 0.24 μm.

In one embodiment, a thickness of the second level metal layer M2 could be in a range of 0.9 μm-1.5 μm, having a minimum line width of 0.9 μm and a minimum space between lines of 0.5 μm, making its minimum pitch 1.4 μm.

In one embodiment, the thick second level metal layer M2 may be covered by passivation and then connected to overlying thick copper RDL (“ReDistribution Layer”) using holes etched in the passivation. The thick copper RDL may be covered by passivation and then contacted using wire bonding to bond pad openings outside the FET device. In one embodiment, the thick second level metal layer M2 may be followed by further via layers and interconnect. In all cases, one masking step is saved by the elimination of the via layer V1 between the first level metal layer M1 and the second level metal layer M2.

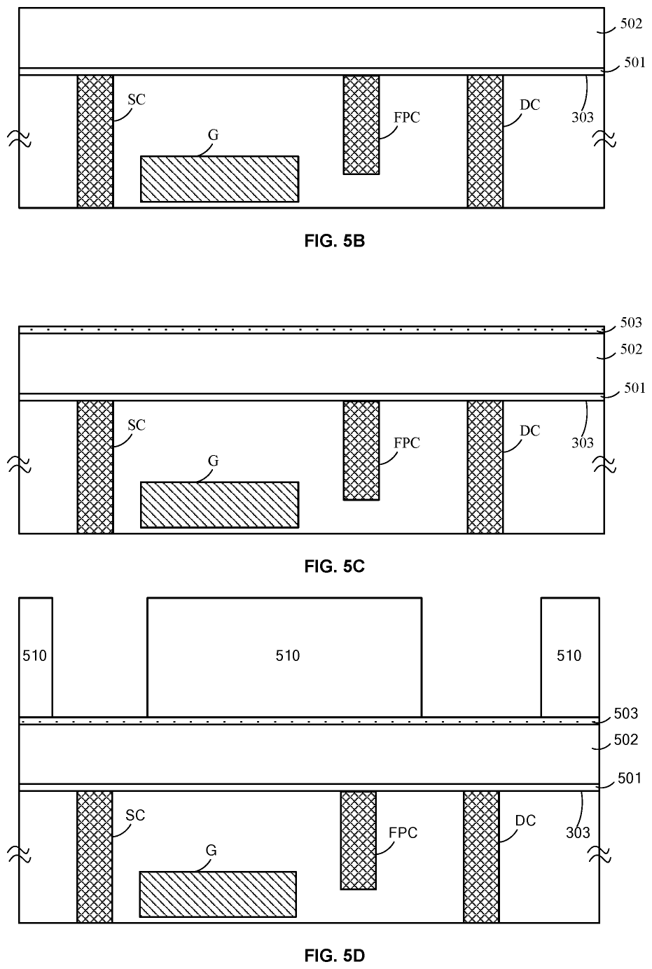

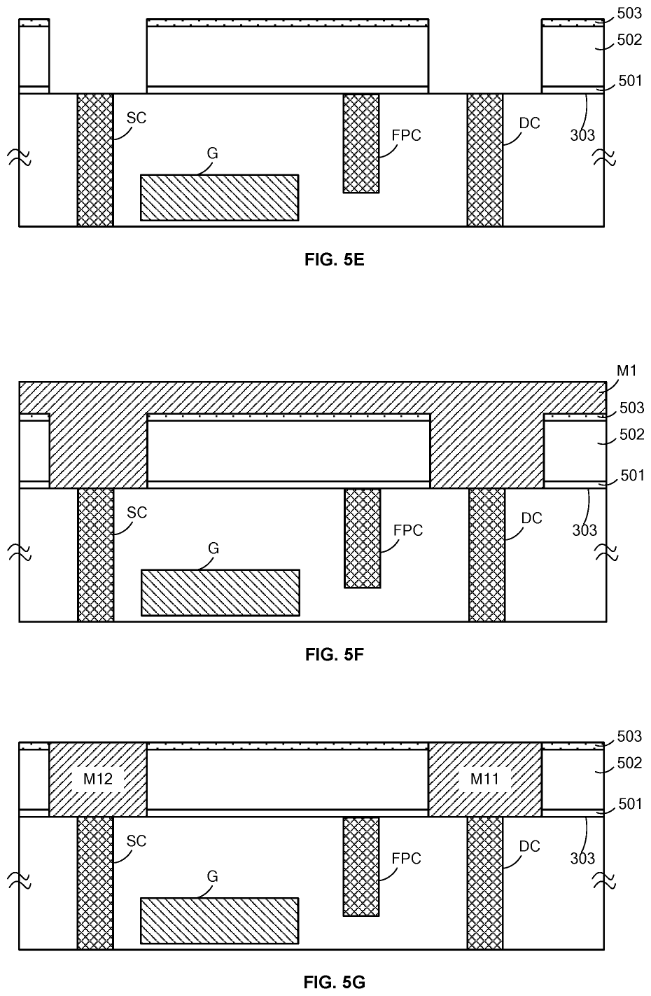

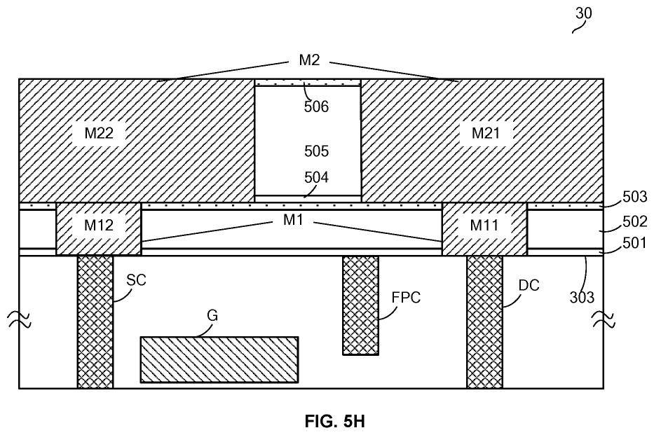

FIG. 5A˜H shows a metal distributing process of a FET device in accordance with an embodiment of the present invention.

As shown in FIG. 5A, an etch-stop layer 501 is deposited on the underlying silicon surface 303. In one embodiment, the etch-stop layer 501 comprises silicon nitride. In one embodiment, the thickness of the etch-stop layer 501 is in a range of 50 nm˜150 nm.

In FIG. 5B, a silicon dioxide layer 502 is deposited on the etch-stop layer 501. The silicon dioxide layer 502 is much thicker than the etch-stop layer 501, and a thickness of the silicon dioxide layer 502 is decided by the thickness requirement of the first level metal layer M1.

In FIG. 5C, a silicon oxynitride layer 503 is deposited on the silicon dioxide layer 502. In one embodiment, the thickness of the silicon oxynitride layer 503 is in a range of 50 nm˜150 nm. The etch-stop layer 501, the silicon dioxide layer 502 and the silicon oxynitride layer 503 constitute the first dielectric layer 301.

In FIG. 5D, a photoresist layer 510 is deposited on the silicon oxynitride layer 503, and is patterned to define the location of the first level metal layer M1.

In FIG. 5E, the first dielectric layer 301 is etched through the openings of the photoresist layer 510. In one embodiment, the silicon dioxide layer 502 and the silicon oxynitride layer 503 are etched through openings of the photoresist layer 510 first, and then the photoresist layer 510 is removed. After that, the etch-stop layer 501 is etched through the openings of the silicon dioxide layer 502 and the silicon oxynitride layer 503.

In FIG. 5F, the first level metal layer M1 is filled in the openings left after etching the first dielectric layer. In one embodiment, the first level metal layer M1 comprises copper. In other embodiments, the first level metal layer M1 may comprise conductive materials like Tin, Nickle, Lead or Aluminum. In one embodiment, filling copper into the openings of the first dielectric layer comprises successively depositing metal barrier layer and copper seed layer, and then plate copper to the whole underlying surface.

In FIG. 5G, a chemical mechanical polishing is performed to the surface to remove the unnecessary metal to obtain a planar surface at a level of the first dielectric layer.

In FIG. 5H, the second dielectric layer 302 is deposited on the underlying surface in a same way that the first dielectric layer 301 is deposited, which comprises depositing an etch-stop layer 504, a silicon dioxide layer 505 and a silicon oxynitride layer 506 successively. The thickness of the silicon dioxide layer 505 is decided by the thickness requirement of the second level metal layer M2. Persons of ordinary skill in the art could decide the thickness of the second level metal layer according to the application requirement. Also, in FIG. 5H, the second dielectric layer 302 is patterned and etched to be filled in with the second level metal layer M2 in the same way that the first level metal layer M1 is formed, and is not illustrated step by step for brevity.

The values of the aforementioned thickness of the metal layers, the line widths of metal lines, the spaces between metal lines, the pitches of the metal stripes are ideal. In real device, the process design rule allows a ±50% deviation from the target spec.

In some embodiments, the dielectric layer may comprise other suitable materials known to persons of ordinary skill in the art.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

1. A metal distributing method for a FET (Field Effect Transistor) device, comprising:
depositing a first dielectric layer on a planar silicon surface;
etching a first level metal layer pattern in the first dielectric layer;
filling in a first level metal layer in openings determined by the first level metal layer pattern;
depositing a second dielectric layer on the first dielectric layer and the first level metal layer; and
etching a second level metal layer pattern in the second dielectric layer;
filling in a second level metal layer in openings determined by the second level metal layer pattern; wherein
the first level metal layer and the second level metal layer are contacted directly, with no via layer in between, and wherein a contact surface of the first level metal layer and the second level metal layer is a planar surface, and is coplanar with top surfaces of the first dielectric layer, and wherein for each contacted first level metal layer and second level metal layer, the first level metal layer is covered by the second level metal layer.

2. The metal distributing method of claim 1, wherein both depositing the first dielectric layer and depositing the second dielectric layer comprise:
depositing an etch-stop layer;
depositing a silicon dioxide layer on the etch-stop layer; and
depositing a silicon oxynitride layer on the silicon dioxide layer.

3. The metal distributing method of claim 2, wherein both etching the first level metal layer pattern in the first dielectric layer and etching the second level metal layer pattern in the second dielectric layer comprise:
forming a photoresist layer to a targeted dielectric layer;
patterning the photoresist layer to expose the targeted dielectric layer;
etching away the targeted dielectric layer through openings of the photoresist layer; and
removing the photoresist layer.

4. The metal distributing method of claim 2, wherein the etch-stop layer comprises silicon nitride.

5. A FET (Field Effect Transistor) device, comprising:
a first dielectric layer on a planar silicon surface;
a first level metal layer damascened in the first dielectric layer;
a second dielectric layer on the first dielectric layer and the first level metal layer; and
a second level metal layer damascened in the second dielectric layer; wherein
the first level metal layer and the second level metal layer are contacted directly, with no via layer in between, and wherein a contact surface of the first level metal layer and the second level metal layer is a planar surface, and is coplanar with top surfaces of the first dielectric layer, and wherein for each contacted first level metal layer and second level metal layer, the first level metal layer is covered by the second level metal layer.

6. The FET device of claim 5, wherein the first dielectric layer and the second dielectric layer comprises:
an etch-stop layer;
a silicon dioxide layer on the etch-stop layer; and
a silicon oxynitride layer on the silicon dioxide layer.

7. The FET device of claim 6, wherein the etch-stop layer comprises silicon nitride.

8. The FET device of claim 6, wherein a thickness of the etch-stop layer is less than 150 nm.

9. The FET device of claim 6, wherein a thickness of the silicon oxynitride layer is less than 150 nm.

10. The FET device of claim 5, wherein a thickness of the first level metal layer is in a range of 0.12 μm-0.38 μm.

11. The FET device of claim 5, wherein a minimum width of lines of the first level metal layer is 0.12 μm.

12. The FET device of claim 5, wherein a minimum space between lines of the first level metal layer is 0.12 μm.

13. The FET device of claim 5, wherein a thickness of the second level metal layer is 0.9 μm˜1.5 μm.

14. The FET device of claim 5, wherein a minimum width of lines of the second level metal layer is 0.9 μm.

15. The FET device of claim 5, wherein a minimum space between lines of the second level metal layer is 0.5 μm.

16. A FET (Field Effect Transistor) device, comprising:
a first level metal layer, patterned to be connected to a source contact and a drain contact, wherein areas of the first level metal layer connected to the source contact are separated from areas of the first level metal layer connected to the drain contact; and
a second level metal layer, patterned to be directly contacted to the first level metal layer, with no via layer in between, wherein areas of the second level metal layer electrically connected to the source contact via the first level metal layer are separated from areas of the second level metal layer electrically connected to the drain contact via the first level metal layer, and wherein a contact surface of the first level metal layer and the second level metal layer is a planar surface, and is coplanar with top surfaces of the first dielectric layer, and wherein for each contacted first level metal layer and second level metal layer, the first level metal layer is covered by the second level metal layer.

17. The FET device of claim 16, wherein a thickness of the first level metal layer is in a range of 0.12 μm˜0.38 μm.

18. The FET device of claim 16, wherein a minimum width of lines of the first level metal layer is 0.12 μm.

19. The FET device of claim 16, wherein a thickness of the second level metal layer is in a range of 0.9 μm˜1.5 μm.

20. The FET device of claim 16, wherein a minimum width of lines of the second level metal layer is 0.9 μm.
